(19) United States
(12) Patent Application Publication
(10) Pub. No.: US 2018/0226136 A1
(43) Pub. Date: Aug. 9, 2018

(54) SYSTEM MANAGEMENT MODE TEST OPERATIONS

(71) Applicant: HEWLETT-PACKARD DEVELOPMENT COMPANY, L.P., Houston, TX (US)

(72) Inventors: Jeffrey Kevin JEANSONNE, Houston, TX (US); Dallas M. BARLOW, Tomball, TX (US); Richard A. BRAMLEY, Jr., Mansfield, MA (US); David PLAQUIN, Bristol (GB); Maugan VILLATEL, Bristol South Gloucestershire (GB)

(21) Appl. No.: 15/749,114

(22) PCT Filed: Jan. 27, 2016
(86) PCT No.: PCT/US2016/015223

§ 371 Date: Jan. 30, 2018

(51) Int. Cl. G11C 29/38; G11C 29/44

(52) U.S. Cl. CPC G11C 29/38; G06F 9/4401; G11C 29/44

(57) ABSTRACT

Example implementations relate to system management mode (SMM) test operations. For example, a system for SMM test operations may include a test mode initiation engine to reboot a computing device, and load an interface firmware engine into system management random access memory (SMRAM) associated with the computing device in response to the reboot, wherein the interface firmware engine includes a production interface firmware engine to perform the test operation on a known address space of the page of SMRAM. The system may include a test operation engine to cause the computing system to operate in a testing mode, wherein the testing mode includes operating the computing system in system management mode (SMM), in response to a test command, and perform a test operation on a page of system management random access memory (SMRAM) associated with the computing device when the computing device is operating in SMM.

### BACKGROUND

Test operations can be performed on a computing system that is operating in system management mode. Such test operations may detect and/or protect against foreign instructions that may be executed when the computing system is operating in system management mode.

### BRIEF DESCRIPTION OF THE DRAWINGS

FIG. 1 illustrates a diagram of an example of a system for system management mode test operations consistent with the disclosure.

FIG. 2 illustrates a diagram of an example computing device consistent with the disclosure.

FIG. 3 illustrates an example system for system management mode test operations consistent with the disclosure.

FIG. 4 illustrates an example system for system management mode test operations consistent with the disclosure.

FIG. 5 illustrates a flow diagram for an example method for system management mode test operations consistent with the disclosure.

FIG. 6 illustrates a diagram of an example of a system for system management mode test operations consistent with the disclosure.

### DETAILED DESCRIPTION

System management mode (SMM) is an operating mode of a central processing unit (CPU) where normal process execution can be suspended and privileged firmware instructions (e.g., code) may be executed. As used herein, “privilege” is the delegation of authority over a computing system. For example, a privilege can be a permission to perform an action (e.g., the ability to access a device or specific memory area, etc.). Privileges can be delegated to system users in varying degrees. Instructions running in SMM may have the highest privileges and can access any device and/or memory location associated with the computing system.

In order to enter SMM, a system management interrupt (SMI) may be used. The SMI may take the form of motherboard hardware and/or chipset signaling via a designated pin on a processor chip, an input/output (I/O) write to a location that firmware has requested the processor chip to act on, and/or a software SMI that may be triggered by system software. In some approaches, the operating system of a computing system may not be allowed to override or disable the SMI. As a result, in an attempt to execute at the highest privilege level, malicious foreign instructions (e.g., rootkits, etc.) may be injected into system management random access memory (SMRAM) to be executed when the computing system is operating in SMM. Once injected and/or executed, these malicious foreign instructions (e.g., software code) may be problematic to computing system operation. For example, instructions that are injected and/or executed in SMM may cause interface firmware (e.g., a basic input/output system) to function improperly or fail. As used herein, “interface firmware” is firmware that performs initialization during a booting process and/or an interface that facilitates communication between an operating system and platform firmware runtime services after booting. Examples of interface firmware include unified extensible firmware interface (UEFI), basic input/output system (BIOS), etc.

However, in order to perform test operations while a computing system is operating in SMM, benign instructions may be injected and/or executed in SMM. In some examples, injecting and/or executing benign instructions into interface firmware associated with the computing device, and monitoring the results can allow validation of the firmware support for prevention and/or detection of malicious instruction injection and/or execution designed to run when the computing system is in SMM. In some examples, SMM test operation can validate the firmware support for detection and/or protection against modification to interface firmware and/or SMRAM associated with a computing device. SMM test operations may validate the firmware support for detection and/or protection against execution of malicious foreign instructions that may be executed when the computing system is operating in SMM.

In some examples, different mechanisms of detection and/or protection against malicious foreign instructions may be tested. For example, one mechanism of detection and/or protection may be provided through enforcement of particular properties associated with pages of SMRAM while the computing system is operating in SMM. In some examples, the mechanisms for detections and/or protections can include enforcement of non-executable and/or write protected properties associated with respective address spaces of memory pages of SMRAM. Another mechanism for detections and/or protections can include enforcement of write protected properties associated with respective address spaces of memory pages of SMRAM.

In some examples, SMM test operations can include operating a computing device in SMM and attempting to execute pages of system management random access memory (SMRAM) that are intended to be non-executable. In some examples, SMM test operations can include operating a computing device in SMM and attempting to modify pages of system management random access memory (SMRAM) that are intended to be write protected. In some examples, attempts to execute non-executable pages and/or attempts to modify write protected pages can be detected, blocked, and/or removed. In some examples, an indication (e.g., an alert, log entry, etc.) that the attempt to execute a non-executable page and/or an attempt to modify a write protected page can be generated and/or stored. As used herein, “test operations” are attempts to execute non-executable SMRAM pages and/or attempts to modify write protected SMRAM pages.

Examples of the disclosure include methods, systems, and computer-readable and executable instructions for SMM test operations. For example, methods, systems, and computer-readable and executable instructions that may allow for testing methodologies for prevention and/or detection of foreign instruction injection and/or execution are described herein. In some examples, SMM test operations may be performed without introducing potential new malicious foreign instructions (e.g., without introducing potential new vulnerabilities), and/or without increasing a risk that existing instructions can be successfully exploited. In some examples, SMM test operations may include injection and/or execution of benign instructions when the computing system is in SMM to trigger the prevention and/or detection mechanisms such that SMRAM behavior can be deterministic and/or predictable.

FIG. 1 illustrates a diagram of an example of a system according to the present disclosure. As shown in the example of FIG. 1, the system 100 may include a database 102 accessible by and in communication with a plurality of engines 104. The engines 104 may include a test mode initiation engine 106 and a test operation engine 108, etc. The plurality of engines 104 may be in communication with interface firmware 107. The system 100 may include additional or fewer engines than illustrated to perform the various functions described herein and examples are not limited to the example shown in FIG. 1.

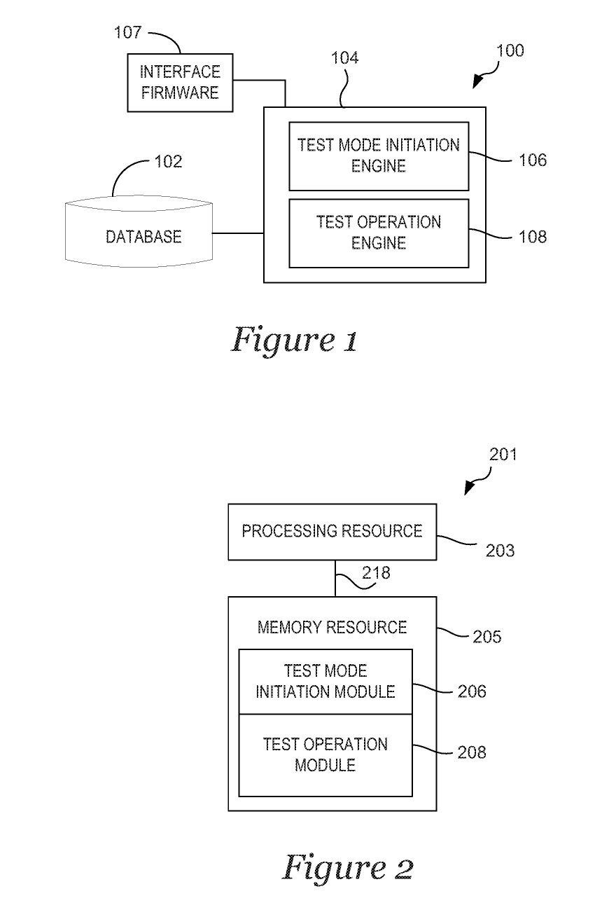

The system 100 may include hardware, e.g., in the form of transistor logic and/or application specific integrated circuitry (ASICs), firmware, and software, e.g., in the form of machine readable and executable instructions (program instructions (programming) stored in a machine readable medium (MRM)) which in cooperation may form a computing device as discussed at least in connection with FIG. 2.

The plurality of engines 104 may include a combination of hardware and software (e.g., program instructions), but at least includes hardware that is configured to perform particular functions, tasks and/or actions. For example, the engines shown in FIG. 1 may be used to generate a test mode initiation command, receive the test mode initiation command and, in response to receiving the test mode initiation command, cause a computing device in communication with the system to operate in system management mode (SMM), and/or inject anomalies to test the protection and/or detection mechanisms. In some examples, the engines shown in FIG. 1 may be used to perform a test operation on a page of system management random access memory (SMRAM) associated with the interface firmware when the computing device is operating in SMM.

The test mode initiation engine 106 may include hardware and/or a combination of hardware and program instructions to reboot a computing device, and load an interface firmware engine into system management random access memory (SMRAM) associated with the computing device in response to the reboot, wherein the interface firmware engine includes a production interface firmware engine to perform the test operation on a known address space of the page of SMRAM. The test mode initiation command can include a runtime firmware application programming interface (API) call. For example, the test mode initiation command can be a MICROSOFT® Windows Management Instrumentation (WMI) call, OpenPegasus call, etc. In some examples, the test mode initiation command can include input received from a user command. For example, a user may actuate a key or button on a user input device as part of generating the test mode initiation command. For example, the test mode initiation engine may receive a user input that includes an indication that the computing device is to enter the testing mode. In some examples, to eliminate a possibility of malicious instructions enabling the test mode, a physically present user can be instructed to actuate a key or button on a user input device as a precondition of generating the test mode initiation command.

In some examples, the interface firmware engine can include a development interface firmware engine to perform the test operation on at least one of an arbitrary address space of the page of SMRAM and an arbitrary address space of random access memory (RAM) associated with the computing device.

In some examples, a computing system in communication with the test mode initiation engine 106 may operate with test mode disabled until the test mode initiation engine 106 generates the test mode initiation command. Once the test mode initiation command is generated, the computing system may enter test mode, as described in more detail, herein. In some examples, the test mode initiation command can include a runtime firmware API call.

In some examples, the test mode may be active until the computing device is rebooted. In some examples, the test mode may be disabled in response to the interface firmware being rebooted N times, where N is a non-negative integer. In some examples, the test mode may remain active until a call indicating that the test mode is to be disabled is received in the form of a runtime firmware application programming interface (API) call.

The test operation engine 108 may include hardware and/or a combination of hardware and program instructions to cause the computing system to operate in a testing mode, wherein the testing mode includes operating the computing system in system management mode (SMM), in response to a test command, and perform a test operation on a page of system management random access memory (SMRAM) associated with the computing device when the computing device is operating in SMM. For example, the test operation engine 108 may cause the computing device to operate in SMM and, in response to the computing device operating in SMM, the test operation engine 108 can perform a test operation on a page of SMRAM.

In some examples, the test operation can include at least one of attempting to modify a page of SMRAM that is designated as a write protected page, attempting to modify a page of SMRAM that is designated as a write protected test page, attempting to modify a page of RAM associated with the computing device that is designated as a write protected page, and attempting to modify a page of RAM associated with the computing device that is designated as a write protected test page. For example, the test operation performed by the development interface firmware engine can include attempting to execute instructions of a non-executable page of memory that is associated with the SMRAM or with RAM associated with the computing system. In some examples, the test operation performed by the development interface firmware engine can include attempting to modify a page of write protected memory that is associated with the SMRAM or with RAM associated with the computing system.

For example, performing the test operation can include attempting to perform the operation at a predetermined address space of the SMRAM. In some examples, the test operation will trigger a page fault, the operation will not be successful, and the computing device can return to normal operation. In some examples, a notification that an attempt to perform the operation and/or that the operation was not successful may be generated and/or provided to, for example, a user. In some examples, the test operation may include at least one of attempting to modify a page of SMRAM that is designated as a write protected page and attempting to modify a page of SMRAM that is designated as a write protected test page.

In some examples, the test operation can include attempting to modify a page of SMRAM that is designated as a write protected page. For example, the test operation can include determining a page of SMRAM and/or RAM that is designated as write protected, and attempting to modify (e.g., read, write, etc.) data contained in the write protected SMRAM page. In some examples, the write protected page can be a write protected test page. In some examples, the test operation can trigger a page fault, the operation will not be successful, and the computing device can return to normal operation. In some examples, a notification that an attempt to perform the operation and/or that the operation was not successful may be generated and/or provided to a user.

In some examples, the test operation can include attempting to execute instructions on a page of SMRAM and/or RAM that is designated as non-executable. For example, the test operation can include determining a page of SMRAM and/or RAM that is designated as non-executable, and attempting to execute instructions stored therein. In some examples, the test operation can trigger a page fault, the operation will not be successful, and the computing device can return to normal operation. In some examples, a notification that an attempt to perform the operation and/or that the operation was not successful may be generated and/or provided to a user.

In some examples, the test operation engine 108 may, in response to receiving subsequent test mode initiation commands (e.g., a runtime firmware API call), reset the configurable number of times the computing system will reboot in the test mode. For example, if the test mode is configured to remain active until the computing system has rebooted a configurable number of times, the test operation engine 108 may reset the number of remaining reboots to the configurable number. As an example, if the test mode is configured to remain active until the computing system has rebooted ten times, and, after the computing system has been rebooted 5 times, a subsequent test mode initiation command is received, the test operation engine 108 may reset the number of times the computing system will reset to ten. In some examples, the interface engine 108 may, in response to receiving subsequent test mode initiation commands, reset the number of remaining reboots to the configurable number without user input.

In some examples, while the computing system is in test mode, a firmware interface (e.g., unified extensible firmware interface, basic input/output system, etc.) can generate an indication (e.g., a warning message, sound, etc.) that the test mode is active when the computing system is rebooted. Examples are not limited to the example engines shown in FIG. 1 and one or more engines described may be combined or may be a sub-engine of another engine. Further, the engines shown may be remote from one another in a distributed computing environment, cloud computing environment, etc.

FIG. 2 illustrates a diagram of an example computing device according to the disclosure. The computing device 201 may utilize hardware, software (e.g., program instructions), firmware, and/or logic to perform a number of functions described herein. The computing device 201 may be any combination of hardware and program instructions configured to share information. The hardware may, for example, include a processing resource 203 and a memory resource 205 (e.g., computer or machine readable medium (CRM/MRM), database, etc.). A processing resource 203, as used herein, may include one or more processors capable of executing instructions stored by the memory resource 205. The processing resource 203 may be implemented in a single device or distributed across multiple devices. The program instructions (e.g., computer or machine readable instructions (CRI/MRI)) may include instructions stored on the memory resource 205 and executable by the processing resource 203 to perform a particular function, task and/or action (e.g. receive a test mode initiation command and, in response to receiving the test mode initiation command, cause interface firmware to operate in system management mode (SMM), perform a test operation on a page of system management random access memory (SMRAM) associated with the interface firmware when the interface firmware is operating in SMM, etc.).

The memory resource 205 may be a non-transitory machine readable medium, include one or more memory components capable of storing instructions that may be executed by a processing resource 203, and may be integrated in a single device or distributed across multiple devices. Further, memory resource 205 may be fully or partially integrated in the same device as processing resource 203 or it may be separate but accessible to that device and processing resource 203. Thus, it is noted that the computing device 201 may be implemented on a participant device, on a server device, on a collection of server devices, and/or a combination of a participant, (e.g., user/consumer endpoint device), and one or more server devices as part of a distributed computing environment, cloud computing environment, etc.

The memory resource 205 may be in communication with the processing resource 203 via a communication link (e.g., a path) 218. The communication link 218 may provide a wired and/or wireless connection between the processing resource 203 and the memory resource 205.

In the example of FIG. 2, the memory resource 205 includes a test mode initiation module 206 and a test operation module 208. As used herein a module may include hardware and program instructions, but includes at least program instruction that may be executed by a processing resource, for example, processing resource 203, to perform a particular task, function and/or action. The plurality of modules may be combined or may be sub-modules of other modules. As shown in FIG. 2, the test mode initiation module 206 and the test operation module 208 may be individual modules located on one memory resource 205. Examples are not so limited, however, and a plurality of modules may be located at separate and distinct memory resource locations, for example, in a distributed computing environment, cloud computing environment, etc.

Each of the plurality of modules may include instructions that when executed by the processing resource 203 may function as an engine such as the engines described in connection with FIG. 1. For example, the test mode initiation module 206 may include instructions that when executed by the processing resource 203 may function as the test mode initiation engine 106 shown in FIG. 1. The test operation module 208 may include instructions that when executed by the processing resource 203 may function as the test operation engine 108 shown in FIG. 1.

Examples are not limited to the example modules shown in FIG. 2 and in some cases a number of modules may operate together to function as a particular engine. Further, the engines and/or modules of FIGS. 1 and 2 may be located in a single system and/or computing device or reside in separate distinct locations in a distributed network, cloud computing, enterprise service environment (e.g., Software as a Service (SaaS) environment), etc.

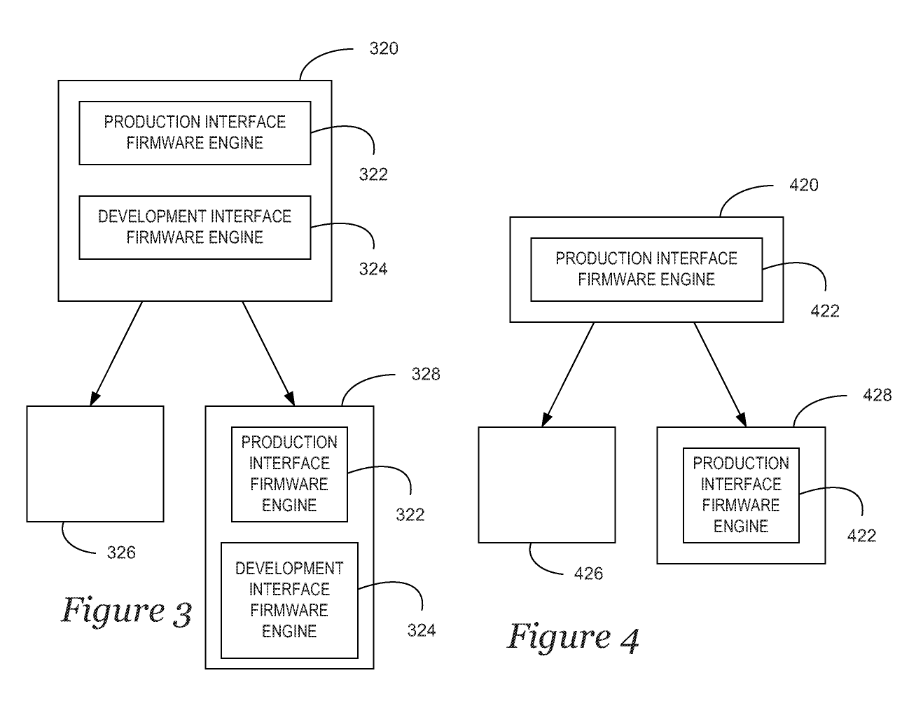

FIG. 3 illustrates an example system for SMM test operation according to the disclosure. In the example of FIG. 3, a boot image 320 can include production interface firmware engine 322 and development interface firmware engine 324. Blocks 326 and 328 illustrate which, if any, of the interface firmware engine 322 and development interface firmware engine 324 are loaded in the SMRAM after the system is booted. For example, at block 326, a test mode has not been enabled, while at block 328, the test mode has been enabled. As illustrated in FIG. 3, in some examples, if the test mode has not been enabled, neither the production interface firmware engine 322 nor the development interface firmware engine 324 are loaded into the SMRAM. Conversely, in some examples, as illustrated at block 328, when the test mode is enabled, both the production interface firmware engine 322 and development interface firmware engine 324 can be loaded into the SMRAM.

In some examples, the development interface firmware engine 324 may be included in firmware associated with a pre-production computing device. For example, a computing device including the development interface firmware engine 324 may be a pre-production computing device that may be utilized for testing purposes before full-scale production of computing devices commences.

In some examples, test operations executed by the production firmware engine 322 may be limited such that they result in deterministic behavior of the interface firmware and/or SMRAM. For example, the production firmware engine 322 may execute test operations on predetermined address locations of the SMRAM, and may therefore receive predictable results and/or behavior from the SMRAM. In some examples, the development interface firmware engine 324 may execute test operations on arbitrary or non-deterministic address locations of the SMRAM, and/or may attempt to execute test operations on any random access memory (RAM) address location either inside or outside of the SMRAM.

FIG. 4 illustrates an example system for SMM test operation according to the disclosure. In the example of FIG. 4, a boot image 420 can include production interface firmware engine 422. Blocks 426 and 428 illustrate if the interface firmware engine is loaded in the SMRAM after the system is booted. For example, at block 426, a test mode has not been enabled, while at block 428, the test mode has been enabled. As illustrated in FIG. 4, in some examples, if the test mode has not been enabled, the production interface firmware engine 422 is not loaded into the SMRAM. Conversely, in some examples, as illustrated at block 428, when the test mode is enabled, the production interface firmware engine 422 can be loaded into the SMRAM. In some examples, the system illustrated in FIG. 4 may be included as part of a production computing device.

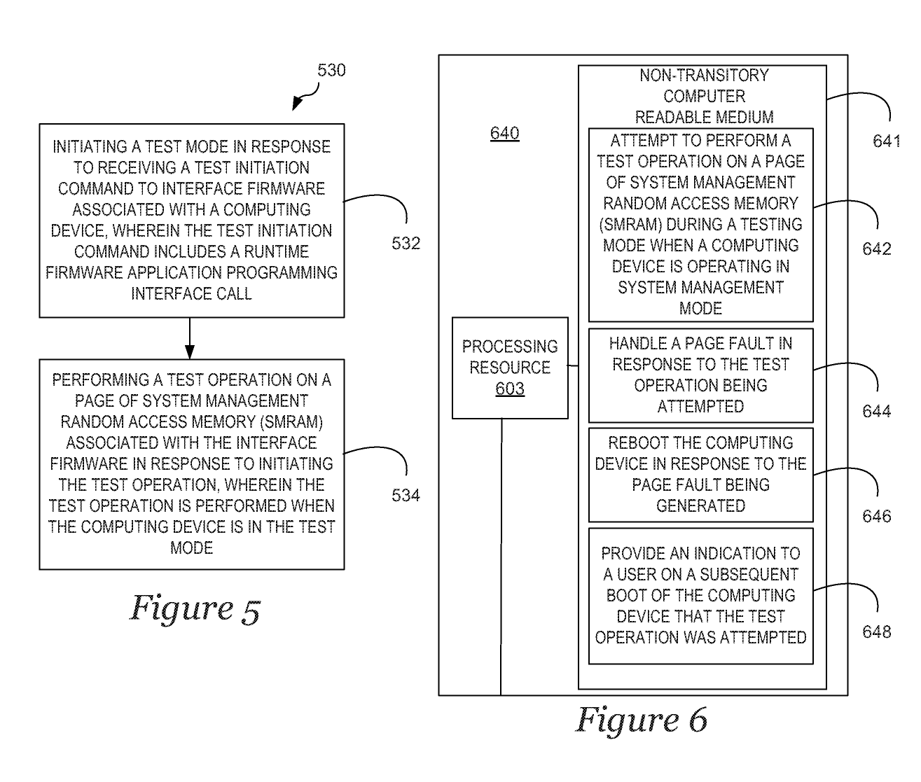

FIG. 5 illustrates a flow diagram for an example method 530 according to the disclosure. In various examples, the method 530 may be performed using the system 100 shown in FIG. 1 and/or the computing device 201 and modules shown in FIG. 2. Examples are not, however, limited to these example systems, devices, engines, and/or modules.

At 532, the method 530 can include initiating a test mode in response to receiving a test initiation command to interface firmware associated with a computing device. In some examples, the test initiation command may include a runtime firmware API call. In some examples, the test initiation command may include input from a user.

At 534, the method 530 can include performing a test operation on a page of system management random access memory (SMRAM) associated with the interface firmware in response to initiating the test operation. In some examples, the test operation can be performed when the computing device is in the test mode. In some examples, the test operation may not be performed unless the computing device is in the test mode.

In some examples, the method 530 can include disabling the test mode in response to the interface firmware being rebooted N times, where N is a non-negative integer. The method 530 can further include resetting a remaining number of interface firmware reboots to N in response to receiving a subsequent runtime firmware API call. In some examples, the method 530 can include performing the test operation by attempting to perform a modify operation on a write protected page of the SMRAM. In some examples, the method 530 can include performing the test operation by attempting to perform an operation on a non-executable page of the SMRAM.

FIG. 6 illustrates a diagram of an example system 640 including a processing resource 603 and non-transitory computer readable medium 641 according to the present disclosure. For example, the system 640 may be an implementation of the example system of FIG. 1 or the example computing device of FIG. 2.

The processing resource 603 may execute instructions stored on the non-transitory computer readable medium 641. For example, the non-transitory computer readable medium 641 may be any type of volatile or non-volatile memory or storage, such as random access memory (RAM), flash memory, read-only memory (ROM), storage volumes, a hard disk, or a combination thereof.

The example medium 641 may store instructions 642 executable by the processing resource 603 to attempt to perform a test operation on a page of system management random access memory (SMRAM) during a testing mode when a computing device is operating in system management mode (SMM).

The example medium 641 may further store instructions 644. The instructions 644 may be executable to handle a page fault in response to the test operation being attempted. For example, the SMRAM and/or the interface firmware may raise an interrupt to terminate the test operation in response to generation of the page fault.

The example medium 641 may further store instructions 646. The instructions 646 may be executable to reboot the computing device in response to the page fault being generated. In some examples, the computing device may reboot in test mode without input from a user or user device. The example medium 641 may further store instructions 646. The instructions 646 may be executable to provide an indication to a user on a subsequent boot of the computing device that the test operation was attempted.

The example medium 641 may further store instructions executable by the processing resource 603 to generate an indication that the test operation was attempted. In some examples, the example medium 641 may further store instructions executable by the processing resource 603 to load information associated with the test operation into the SMRAM in response to a determination that the computing device is in the testing mode.

In the foregoing detailed description of the present disclosure, reference is made to the accompanying drawings that form a part hereof, and in which is shown by way of illustration how examples of the disclosure may be practiced. These examples are described in sufficient detail to enable those of ordinary skill in the art to practice the examples of this disclosure, and it is to be understood that other examples may be utilized and that process, electrical, and/or structural changes may be made without departing from the scope of the present disclosure.

The figures herein follow a numbering convention in which the first digit corresponds to the drawing figure number and the remaining digits identify an element or component in the drawing. For example, reference numeral 102 may refer to element “02” in FIG. 1 and an analogous element may be identified by reference numeral 203 in FIG. 2. Elements shown in the various figures herein can be added, exchanged, and/or eliminated so as to provide a number of additional examples of the present disclosure. In addition, the proportion and the relative scale of the elements provided in the figures are intended to illustrate the examples of the present disclosure, and should not be taken in a limiting sense. Further, as used herein, “a number of” an element and/or feature can refer to one or more of such elements and/or features.

As used herein, “logic” is an alternative or additional processing resource to perform a particular action and/or function, etc., described herein, which includes hardware, for example, various forms of transistor logic, application specific integrated circuits (ASICs), etc., as opposed to computer executable instructions, for example, software firmware, etc., stored in memory and executable by a processor.

What is claimed:

1. A system, comprising:
a test mode initiation engine to:
reboot a computing device;
load an interface firmware engine into system management random access memory (SMRAM) associated with the computing device in response to the reboot, wherein the interface firmware engine includes a production interface firmware engine to perform the test operation on a known address space of the page of SMRAM; and
a test operation engine to:
cause the computing system to operate in a testing mode, wherein the testing mode includes operating the computing system in system management mode (SMM), in response to a test command; and
perform a test operation on a page of system management random access memory (SMRAM) associated with the computing device when the computing device is operating in SMM.

2. The system of claim 1, wherein the interface firmware engine includes a development interface firmware engine to perform the test operation on at least one of an arbitrary address space of the page of SMRAM and an arbitrary address space of random access memory (RAM) associated with the computing device.

3. The system of claim 2, wherein the test operation includes at least one of attempting to modify a page of SMRAM that is designated as a write protected page, attempting to modify a page of SMRAM that is designated as a write protected test page, attempting to modify a page of RAM associated with the computing device that is designated as a write protected page, and attempting to modify a page of RAM associated with the computing device that is designated as a write protected test page.

4. The system of claim 1, wherein the test mode initiation command includes a runtime firmware application programming interface (API) call.

5. The system of claim 1, wherein the test mode initiation engine is to receive a user input that includes an indication that the computing device is to enter the testing mode.

6. The system of claim 1, wherein the test operation includes attempting to perform an operation on a non-executable page of SMRAM.

7. The system of claim 1, wherein attempting to perform the operation includes attempting to perform the test operation at a predetermined address location of the SMRAM.

8. The system of claim 1, wherein the test operation includes at least one of attempting to modify a page of SMRAM that is designated as a write protected page and attempting to modify a page of SMRAM that is designated as a write protected test page.

9. A method, comprising:
initiating a test mode in response to receiving a test initiation command to interface firmware associated with a computing device, wherein the test initiation command includes a runtime firmware application programming interface (API) call; and
performing a test operation on a page of system management random access memory (SMRAM) associated with the interface firmware in response to the test operation, wherein the test operation is performed when the computing device is in the test mode.

10. The method of claim 9, further comprising disabling the test mode in response to the interface firmware being rebooted N times, where N is a non-negative integer.

11. The method of claim 10, further comprising resetting a remaining number of interface firmware reboots to N in response to receiving a subsequent runtime firmware API call.

12. The method of claim 9, wherein performing the test operation includes attempting to perform a modify operation on a write protected page of the SMRAM.

13. The method of claim 9, wherein performing the test operation includes attempting to perform an operation on a non-executable page of the SMRAM.

14. A non-transitory computer readable medium storing instructions executable by a processing resource to:
attempt to perform a test operation on a page of system management random access memory (SMRAM) during a testing mode when a computing device is operating in system management mode (SMM);
handle a page fault generated in response to the test operation being attempted;
reboot the computing device in response to the page fault being generated; and
provide an indication to a user on a subsequent boot of the computing device that the test operation was attempted.

15. The non-transitory computer readable medium of claim 13, wherein the instructions are executable by the processing resource to load information associated with the test operation into the SMRAM in response to a determination that the computing device is in the testing mode.
